(19) United States
(12) Patent Application Publication
(10) Pub. No.: US 2025/0308032 A1
(43) Pub. Date: Oct. 2, 2025

(54) EDGE DETECTION FOR GREYSCALE IMAGES

(71) Applicant: Applied Materials Israel Ltd., Rehovot (IL)

(72) Inventor: Charles VALADE, Fontaine (FR)

(21) Appl. No.: 18/625,121

(22) Filed: Apr. 2, 2024

(51) Int. Cl. G06T 7/13; G06T 7/00; G06T 7/50

(52) U.S. Cl. CPC G06T 7/13; G06T 7/0004; G06T 7/50; G06T 2207/10061; G06T 2207/30148

(57) ABSTRACT

According to the presently disclosed subject matter, to improve edge detection obtained by traditional shape-based analysis and obtain edge detection accurately targeting a certain desired feature (e.g., contours, shape and/or pattern) in the image, greyscale dependent transformation is applied in addition to the shape-based analysis. In this manner the shape-based analysis identifies the shape or pattern of interest, and the greyscale dependent transformation further transforms the shape-based analysis output, such that visibility of pixels that fall within a predetermined pixel value range is increased. By this, ambiguities that result from the inability of the shape-based analysis to discriminate between similar edges up to a linearity, are resolved, and the desired feature (e.g., contour shape and/or pattern) can be identified.

### TECHNICAL FIELD

The presently disclosed subject matter is related to edge detection in greyscale images and to the processing of grey level images of a semiconductor specimen during semiconductor examination.

### BACKGROUND

A wafer is a thin, usually circular slice of semiconductor material, frequently made of silicon, that serves as a substrate for manufacturing integrated circuits. A semiconductor die is an independent and discrete component of an integrated circuit (e.g., an individual computer processor) that contains a specific set of electronic components, all fabricated together on the same wafer. Generally, during the manufacturing process, multiple dies are created on a single wafer, each being a copy of the same integrated circuit, effectively yielding identical copies of the integrated circuit design.

Current demands for high density and performance associated with large-scale and up to ultra-large-scale integration of fabricated devices require submicron features, increased transistor and circuit speeds, and improved reliability. As semiconductor processes progress, pattern dimensions such as line width, and other types of critical dimensions, are continuously shrunk. Such demands require formation of device features with high precision and uniformity, which, in turn, necessitates careful monitoring of the fabrication process, including automated examination of the devices while they are still in the form of semiconductor wafers.

### GENERAL DESCRIPTION

The presently disclosed subject matter includes a computer-implemented method and a computer system dedicated for processing grey level (or “greyscale”) images, and applying edge detection and contour extraction on the grey level images. More specifically, the method and system disclosed herein combine transformation by shape-based analysis with greyscale dependent transformation, to selectively detect edges and contours in the grey level image which are characterized by specific values (e.g., pixels). Unlike traditional shape-based analysis, this novel approach enables to discriminate, during edge detection, between shapes in the grey level image which are similar up to a linearity.

According to a first aspect of the presently disclosed subject matter there is provided a computer implemented method of processing grey level (GL) images; where according to some examples the grey level images are images of a semiconductor specimen that were generated by an examination tool used for scanning the semiconductor specimen; the method comprising:
applying a shape-based analysis to a region of interest (ROI) in a grey level image, to thereby obtain a transformed ROI comprising pixels transformed by the shape-based analysis; wherein the ROI comprises the entire image or part thereof;
calculating, for each transformed pixel i, j in the transformed ROI, a respective regularized pixel value A_{i,j}^{r}, based on a ratio between a respective transformed pixel value A_{i,j} or a functional variation thereof and (an absolute value of) a difference between the original grey level pixel value P_{i,j} before transformation, and a target grey level pixel value Pₜ or a functional variation of the difference; wherein the target grey level pixel value Pₜ represents a grey level value (e.g., center value) of at least one sought-after edge (which is part of a contour, shape, and/or pattern of interest) in the grey level image; and
generating an output image, composed of the regularized pixel values, in which visibility of the at least one sought-after edge in the grey level image is emphasized, while visibility of other edges in the grey level image is diminished.

In addition to the above features, the method according to this aspect of the presently disclosed subject matter can optionally comprise one or more of features (i) to (vii) below, in any technically possible and technically possible combination or permutation:
i. Wherein the computer-implemented method further comprises:
   analyzing the at least one sought-after edge to detect features that characterize the semiconductor specimen; and using the features for detecting defects of interest in the semiconductor specimen.
ii. The computer-implemented method further comprising utilizing an examination tool for scanning the semiconductor specimen and generating the grey level image. According to one example the examination tool is a Scanning Electron Microscope (SEM).
iii. Wherein, according to some examples, the calculation of the respective regularized pixel value A_{i,j}^{r} includes calculating a respective regularization coefficient C_{i,j} expressed as

$$\frac{1}{\vert {P}_{t -} {P}_{i , j} \vert} ,$$

or any mathematical equivalent thereof;
   wherein:
   C_{i,j} is the regularization coefficient calculated for pixel i, j;
   Pₜ is a target pixel grey level value;
   P_{i,j} is an original pixel grey level value of pixel i, j before application of the shape-based analysis;
   the method comprising applying (e.g., multiplying) the respective regularization coefficient on the transformed pixel value A_{i,j} to thereby obtain the respective regularized pixel value A_{i,j}^{r}.
iv. Wherein, according to some examples, the calculation of the respective regularized pixel value A_{i,j}^{r} includes calculating a respective regularization coefficient C_{i,j} expressed as

$$\frac{{P}_{gap}}{max ( \vert {P}_{t -} {P}_{i , j ,} \vert , {P}_{gap} )}$$

or any mathematical equivalent thereof;
   wherein:
   C_{i,j} is the regularization coefficient calculated for pixel i, j;
   Pₜ is a target pixel grey level value;
   P_{i,j} is an original pixel grey level value of pixel i, j before application of the shape-based analysis; and
   P_{gap} is a pixel value lower-bound constraint;
   the method comprising applying (e.g., multiplying) the respective regularization coefficient on the transformed pixel value A_{i,j} to thereby obtain the respective regularized pixel value A_{i,j}^{r}.
v. Wherein, according to some examples, the calculation of the respective regularized pixel value A_{i,j}^{r} includes calculating a respective regularization coefficient C_{i,j} expressed as

$$\frac{{P}_{gap}}{\sqrt{( {( {P}_{t -} {P}_{i , j} )}^{2} + {P}_{gap}^{2} )}}$$

or any mathematical equivalent thereof;
   wherein:
   C_{i,j} is the regularization coefficient calculated for pixel i, j;
   Pₜ is a target pixel grey level value;
   P_{i,j} is an original pixel grey level value of pixel i, j before application of the shape-based analysis; and
   P_{gap} is a pixel value lower-bound constraint;
   the method comprising applying the respective regularization coefficient on the transformed pixel value A_{i,j} to thereby obtain the respective regularized pixel value A_{i,j}^{r}.
vi. In some examples the method further comprises:
   defining the target grey level pixel value Pₜ according to pixel values characterizing the at least one sought-after edge.
vii. In some examples, the method further comprises:
   defining the value of P_{gap} according to characteristics of the grey level image and Pₜ.

According to a second aspect of the presently disclosed subject matter there is provided a computer system configured and operable to process grey level (GL) images; wherein, according to some examples, the GL images are images of a semiconductor specimen that were generated by an examination tool that is used for scanning the semiconductor specimen; the computer system comprising a processing circuitry, comprising at least one processor and configured to:
apply a shape-based analysis to a region of interest (ROI) in a grey level image, to thereby obtain a transformed ROI comprising pixels transformed by the shape-based analysis; wherein the ROI comprises the entire image or part thereof;
calculate, for each transformed pixel i, j in the transformed ROI, a respective regularized pixel value A_{i,j}^{r}, based on a ratio between a respective transformed pixel value A_{i,j} or a functional variation thereof and (an absolute value of), a difference between the original grey level pixel value P_{i,j} before transformation, and a target grey level pixel value Pₜ or a functional variation of the difference; wherein the grey level pixel value Pₜ represents a grey level value (e.g., center value) of at least one sought-after edge in the grey level image; and
generate an output image, composed of the regularized pixel values, in which visibility of the at least one sought-after edge in the grey level image is emphasized, while visibility of other edges in the grey level image is diminished.

The presently disclosed subject matter further contemplates a non-transitory computer readable medium comprising instructions that, when executed by a computer, cause the computer to perform a method of processing grey level (GL) images as described above with respect to the first aspect.

The presently disclosed subject matter further contemplates a computer program product comprising instructions which, when the program is executed by a computer, cause the computer to carry out a method of processing grey level (GL) images as described above with respect to the first aspect.

The presently disclosed subject matter further contemplates an examination system dedicated for examining semiconductor specimens, e.g., as part of as part of a semiconductor manufacturing process, the system comprising an examination tool (e.g., SEM) and at least one processing circuitry configured as described above with respect to the second aspect.

The system, the non-transitory program storage device, the computer program product, and the examination system disclosed above, can optionally comprise one or more of features (i) to (vii) listed above, mutatis mutandis, in any technically possible combination or permutation.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 shows (i) an illustrative example of a grey level SEM image of a shape having distinct boundaries visible by the grey level difference of the pixels and (ii) a corresponding graph showing the grey level pixel values along a scanning line;

FIG. 2 shows (i) an example of a grey level SEM image showing a pattern that includes transition from black to dark grey, and then from grey to light grey, and (ii) a corresponding graph showing the grey level pixel values along a scanning line, a first shape-based response and a second shape-based response applied on the image;

FIG. 3 shows (i) shows the result of the shape-based analysis, where two edges indicated by a white parameter are apparent, and (ii) an edge detection result by shape-based analysis;

FIG. 4 illustrates a generalized block diagram of an examination system in accordance with certain examples of the presently disclosed subject matter;

FIG. 5 is a high-level flowchart showing operations carried out as part of a process that involves edge detection, in accordance with certain examples of the presently disclosed subject matter;

FIG. 6 is a flowchart showing operations carried out as part of edge detection, in accordance with certain examples of the presently disclosed subject matter;

FIG. 7 is a graph plotting the regularization coefficients (ordinate) relative to the corresponding grey level difference |Pₜ−P_{i,j}| (abscissa), in accordance with certain examples of the presently disclosed subject matter;

FIG. 8a shows (i) an example of a grey level SEM output image and (ii) the same image transformed by shape-based analysis, in accordance with certain examples of the presently disclosed subject matter; and

FIG. 8b shows an example of the SEM output image transformed using both shape-based analysis and regularization coefficient, using a first Pₜ value (i) and a second Pₜ value (ii), in accordance with certain examples of the presently disclosed subject matter.

### DETAILED DESCRIPTION

Semiconductor examination is an important part of the semiconductors manufacturing process. This includes the inspection of semiconductor wafers for defects of interest (DOIs) to ensure their quality. There are various types of examination tools which can be used in the semiconductor examination process, including for example optical microscopy, electron beam inspection machines (e.g., a Scanning Electron Microscope (SEM), or a Transmission Electron Microscope (TEM), etc.), Atomic Force Microscopy (AFM), X-ray microscopy, and so on. These tools are used for scanning semiconductor specimens (e.g., an entire wafer, an entire die, or portions thereof) and generating grey level (GL) images (also referred to as “grayscale” images).

In the resulting GL images (in the context of semiconductors also referred to herein as “examination output images”), each pixel represents an intensity value, e.g. on a scale from 0 (black) to 255 (white) for 8-bit images. These intensity values reflect various properties of the sample, such as material composition, surface topology, or the presence of features and defects. The images are processed to identify flaws like cracks, misalignments, or impurities. These imperfections can significantly affect the yield rate as well as the performance of the final product. Even a small fault in a semiconductor can have a substantial impact on the functionality of electronic devices such as computers, smartphones, and other digital equipment, making this inspection process critical for maintaining the reliability and efficiency of electronic components, as well as reducing manufacturing costs and waste, as defects which are left unnoticed can cause significant loss of resources.

Edge detection in image processing is a computational technique dedicated to identifying sharp changes, or “edges,” within an image. These edges mark significant transitions in image brightness and are important for outlining features such as contours, shapes, and patterns within the visual information. Acting as a foundational step in various analytical procedures, edge detection facilitates the extraction and examination of data required for object identification, feature recognition, and analysis.

In the semiconductor industry, edge detection is essential for interpreting examination output images, such as those from Scanning Electron Microscopes (SEM), where it aids in evaluating the geometry and arrangement of semiconductor samples and in identifying defects. Edge detection algorithms are often applied as part of a process of transforming detected edges into well-defined contours. This transformation facilitates a detailed analysis of the material's patterns, revealing critical insights into sizes, shapes, and potential anomalies, thereby enhancing the precision and effectiveness of semiconductor inspections and quality control.

As used herein the term ‘edge detection’ should be broadly construed to include not only edge identification per se (i.e., sharp discontinuities), but also any process that involves or relies on edge detection, such as contour extraction and pattern recognition. This inclusive interpretation reflects the technique's applicability, beyond mere edge delineation, to include the comprehensive extraction and analysis of shapes, patterns, and textures within the visual data.

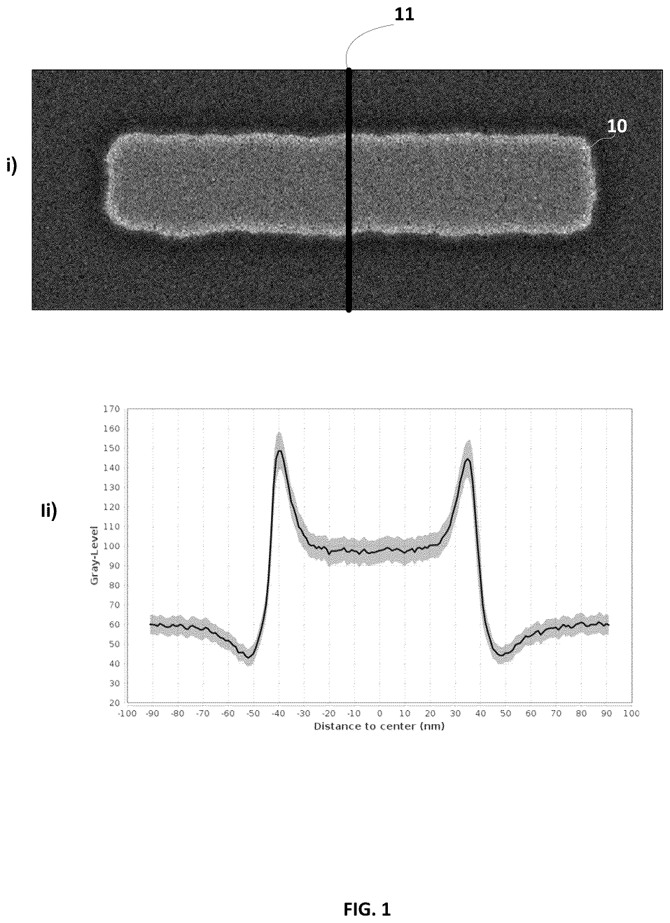

FIG. 1 (i) shows an illustrative example of an examination output image, in this case a GL SEM image of a shape 10 having distinct boundaries visible by the greyscale differences of the pixels. Line 11 crossing the shape at the center, illustrates a SEM scanning line. FIG. 1 (ii) further includes a graph showing the greyscale values of the pixels along the scanning line (here an 8-bit image). As apparent from the graph, the edges of the shape are discernable based on the pixel values.

Some examination tools are known to provide GL images which exhibit noise, primarily due to the stochastic nature of electron interactions with the sample. This noise is not merely visual, but impacts the GL of the image, introducing random fluctuations that can obscure fine details. Furthermore, GL SEM images are characterized by high variability in the grayscale values, especially evident in images captured under different conditions or at different times. This variability can arise, for example, from changes in environmental factors, sample preparation, or imaging parameters, leading to significant differences in image appearance.

Consequently, shape-based image analysis algorithms, which are commonly used in edge detection techniques, are often the preferred tools for interpreting and analyzing GL SEM output images (as well as for other types of GL images). Unlike methods that rely on absolute grayscale values, which are directly affected by the aforementioned noise and variability, shape-based approaches focus on the geometry and structure within the image. Techniques such as gradient (slope) detection, extremum identification in grayscale values, and kernel convolution, are employed to identify and analyze edges and contours.

However, traditional shape-based image analysis primarily captures spatial frequency information and accordingly are characterized by an inherent linearity. Accordingly, such tools struggle to distinguish between shapes that, while structurally similar, differentiate in their spatial transformation such as scaling (contrast) or translation (brightness).

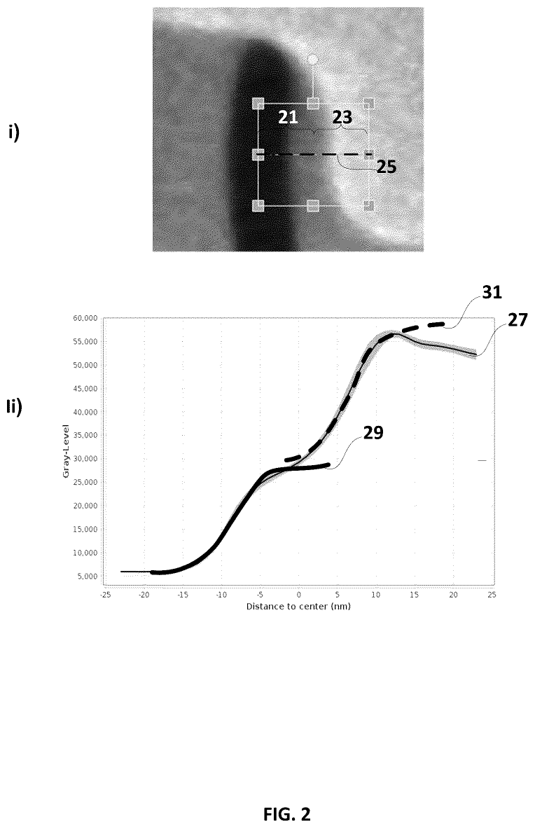

FIG. 2 (i) is an example of GL SEM image showing a pattern that includes transition (21) from black to dark grey and then transition (23) from dark grey to light grey/white. Considering the region of interest (ROI) marked by the rectangle, and assuming it is desired to identify the edge surrounding the black region, using shape-based analysis on the ROI would result in two similar responses. FIG. 2 (ii) shows a first response (29) that corresponds to the transition from black to dark grey (21), and a second response (31) that corresponds to the transition from dark grey to light gray (23), characterized by higher pixel values than the first. As shown in the figure, the two responses (overlaid on the pixel values 27 in the graph) have a very similar profile up to linearity, thus it would be difficult to determine which response corresponds to the shape sought after.

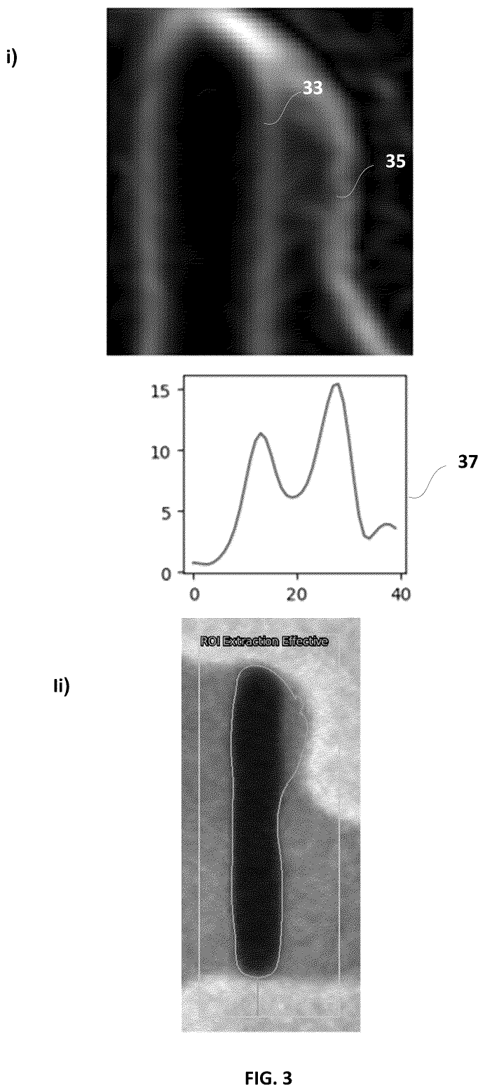

FIG. 3 (i) shows the result of the shape-based analysis where two edges indicated by a white parameter are apparent, one edge marking the contour of the black region (33), and the other marking the contour of the grey region (35). As apparent from the appended graph 37 in FIG. 3, the second response, corresponding to the transition (23) from grey to light grey, is characterized by a higher intensity than the first response.

FIG. 3 (ii) further shows a possible edge detection result by shape-based analysis applied on the image where the identified contour includes part of the dark grey pixels, selected due to the higher intensity of the transition of the second response. These undesired results are often encountered during edge detection of GL images such as examination output images generated by semiconductor examination tools like SEM.

The presently disclosed subject matter includes a new and improved computer implemented edge detection technique with improved accuracy of detection of sought-after edges (e.g., being part of contours, shapes, or patterns of interest) in grayscale images such as examination output images.

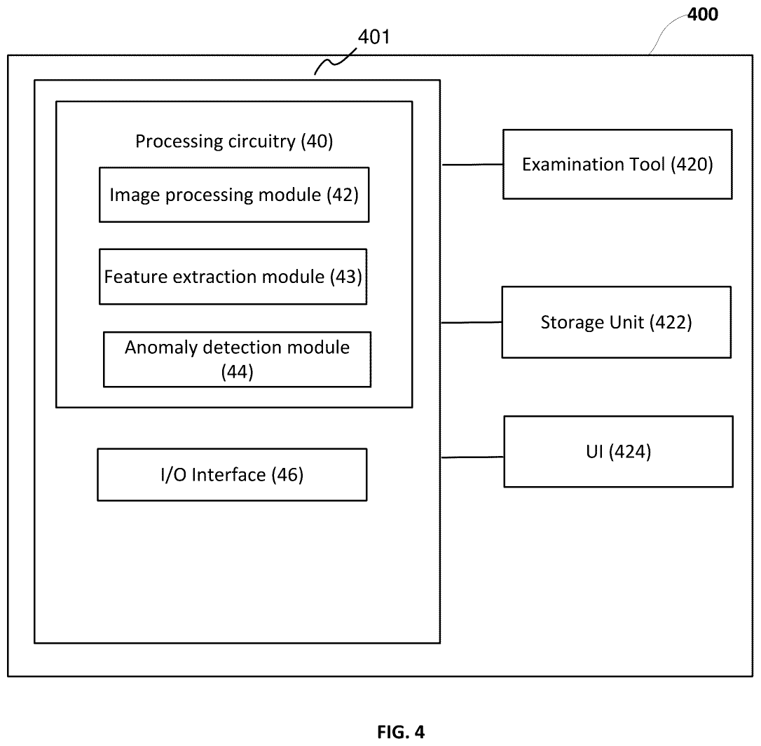

Bearing the above in mind, attention is drawn to FIG. 4, which is a generalized block diagram illustration of a computer system 401 configured with edge detection capabilities according to examples of the presently disclosed subject matter. FIG. 4 shows a non-limiting example where system 401 is integrated in a semiconductor examination system 100. Examination system 400 can be used for examination of a semiconductor specimen (e.g., a wafer, a die, or parts thereof) e.g., as part of the specimen fabrication process. The examination referred to herein can be construed to include any kind of operations related to defect inspection/detection, defect classification, segmentation, metrology operations, etc., with respect to the specimen. System 400 can comprise one or more examination tools 420 configured to scan a specimen and capture images thereof to be further processed for various examination applications.

The term “examination tool(s)” used herein should be expansively construed to cover any tools that can be used in examination-related processes. As mentioned above, the examination tools 420 include, for example, one or more inspection tools that generate grayscale output images of an examined semiconductor specimen (e.g., by scanning or imaging). An inspection tool is configured to scan a specimen (e.g., an entire wafer, an entire die, or portions thereof) to capture inspection images (typically, at a relatively high-speed and/or low-resolution) for detection of potential defects (i.e., defect candidates). Particularly, an inspection tool can be any type of electron microscopy device which generates grey-level (GL) images.

According to one example, an inspection tool is a Scanning Electron Microscope (SEM). SEMs are a type of electron microscope that produces grayscale images of a specimen by scanning it with a focused beam of electrons. The operation of an SEM involves directing a focused beam of high-energy electrons toward a sample surface. This electron beam is generated by an electron gun and then precisely focused and directed using electromagnetic lenses. As the electron beam scans across the surface of the sample, it interacts with the atoms, leading to various outcomes such as the emission of secondary electrons, backscattered electrons, and characteristic X-rays.

The detection of secondary electrons (emitted from atoms near the surface) allows for high-resolution imaging of the sample's topography. Backscattered electrons, which are the primary electrons electromagnetically deviated from the sample atoms, provide information on the composition and contrast based on atomic number differences within the sample.

Detectors designed for specific types of emissions capture the signals resulting from these interactions. This collected data is then processed to produce a grayscale image, indicating the quantity of electrons captured by the detector. This number of collected electrons varies, depending on the surface topography, composition, or other properties of the sample. Through this process, SEMs (Scanning Electron Microscopes) can generate highly detailed grayscale images of the sample surface at magnification levels unattainable with traditional optical microscopes, providing precise inspection and measurement capabilities during the manufacturing of semiconductor wafers.

In some cases, the examination tools 420 further include a review tool configured to provide a detailed examination of specific areas on a semiconductor wafer, particularly those areas where defects or anomalies have been identified by an inspection tool. It allows for close-up, in-depth analysis of these defects. A review tool is usually configured to inspect fragments of a specimen, one at a time (typically, at a relatively low-speed and/or high-resolution) and generate (GL) images of the reviewed area. By way of example, the review tool can be an electron beam tool, such as, e.g., scanning electron microscopy (SEM), etc.

The inspection tool and review tool can be different tools located at the same or at different locations, or a single tool operated in two different modes. In some cases, the same examination tool can provide low-resolution image data and high-resolution image data. The resulting image data (low-resolution image data and/or high-resolution image data) can be transmitted—directly or via one or more intermediate systems—to system 401. Notably, the present disclosure is not limited to any specific type of examination tools and/or the resolution of image data resulting from the examination tools. In some cases, at least one of the examination tools 420 has metrology capabilities and can be configured to capture images and perform metrology operations on the captured images. Such an examination tool is also referred to as a metrology tool.

Per the illustrated example, computer system 400 comprises processing circuitry 40 configured to execute various processing operations. This includes processing images of a semiconductor specimen (e.g., a wafer, a die, or parts thereof) generated by an examination tool 420 (e.g., SEM) and identifying and delineating the boundaries of various features (e.g., contour, shape, or pattern of interest) of the semiconductor specimens captured in the images.

Processing circuitry 40 can comprise one or more processors and one or more memories (not shown). In some examples, the processing circuitry is configured to execute several functional modules in accordance with computer-readable instructions implemented on a non-transitory computer-readable memory comprised in the processing circuitry. Such functional modules are referred to hereinafter as comprised in the processing circuitry.

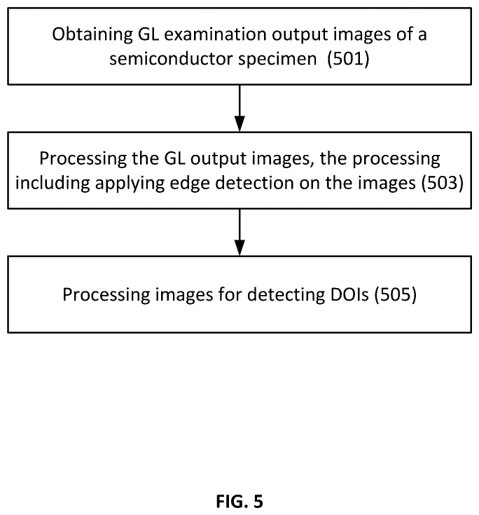

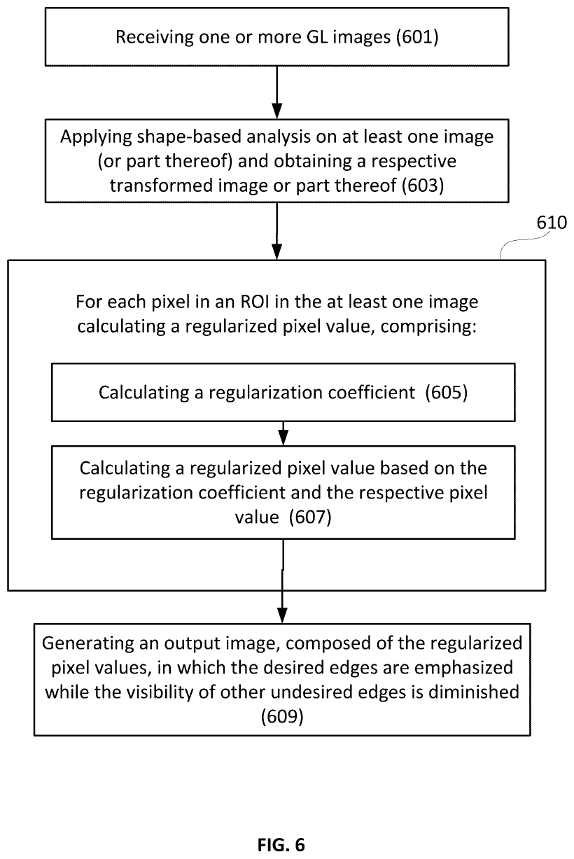

The functional modules include for example image processing module 42 configured to process semiconductor specimen images, apply edge detection, and identify contours, shapes, and/or patterns in the images. Specific operations related to image processing module 40 and particularly image processing module 40 are described below with reference to FIGS. 5 and 6.

In some examples, processing circuitry 40 further comprises an anomaly detection module 44 configured to process the images received from the examination tool for detecting defects in the imaged semiconductor specimens. In some examples, examination system 400 is configured with automatic defect examination capability in a semiconductor specimen where, as part of the semiconductor fabrication process, examination tool output images are processed by system 401 in runtime for classifying candidate defects identified in the images, and detecting DOIs.

Anomaly detection module 44 is configured to implement one or more DOI detection algorithms. According to some examples, DOI detection algorithm is implemented as a machine learning (ML) classifier trained on a training dataset comprising examination tool output images. The trained ML classifier is applied on test data comprising one or more examination tool output images (e.g., GL SEM images). In this context, one or more dedicated modules (e.g., feature extraction module 43) can be configured to use the information obtained by the image processing module 42 to identify certain features which are used as input to a ML classifier trained for detecting DOIs.

According to some examples, system 400 can comprise or be otherwise operatively connected to a data-storage unit 422. The data storage unit 422 can be configured to store any data necessary for operating system 401, including for example computer software which is loaded during execution of any one of the modules described above, intermediate processing results generated by system 401, examination output images, outputs of image processing module, etc.

In some embodiments, system 400 can optionally comprise a user interface 424 to enable user interaction with system 400 and/or system 401. The user interface can include a display device, user interaction devices (e.g., computer mouse and keyboard) and a graphical user interface (GUI) configured to enable, inter alia, user-specified inputs related to system 400 and/or 401. For instance, the user may be provided, through the GUI, with options of defining certain operations and/or parameters (e.g. P_{gap} Or Pₜ described below). The user may also view on the display the processing results or intermediate processing results, such as, e.g., outputs of image processing module 42, a graphical presentation, or simulation of the results, etc.

It should be further noted that in some examples at least some of examination tools 420, storage unit 422, and/or UI 424, can be external to the examination system 400 and operate in data communication with systems 400 and 401 e.g., via I/O interface 46.

Turning to FIG. 5, this shows a high-level flow chart of operations carried out as part of a process that involves edge detection, in accordance with some examples of the presently disclosed subject matter. By way of non-limiting example only, operations in FIGS. 5 and 6 are described with reference to the system components shown in FIG. 4.

Initially GL images are obtained (block 501). This can be during semiconductor fabrication, where a fabricated semiconductor specimen is examined using an examination tool 420 (inspection tool and/or a review tool (e.g., SEM)) that generates GL examination output images (e.g., GL SEM images). Inspection of a wafer may involve using an inspection tool for performing multiple passes over the wafer, where a respective strip or swath of a semiconductor specimen is scanned during each pass.

The GL images generated by the examination tool are processed to detect features in the images, such as contours, shapes and/or patterns, characterizing the semiconductor specimens that were scanned (e.g., by image processing module 42). As part of this process, edge detection is applied on the GL images, as further disclosed herein (503).

In some examples, once the features have been identified, the images can be processed for detecting DOIs (505). For instance, during an initial processing phase the GL images are processed to determine whether they include any candidate defects. Then images that are identified to include candidate defects are further processed to determine whether the candidate defects are DOIs or noise (e.g., by anomaly detection module 40).

FIG. 6 is a flowchart of operations carried out as part of an edge detection process, according to examples of the presently disclosed subject matter. FIG. 6 provide a more detailed description of operations related to blocks 501 and 503 in FIG. 5.

At block 501 one or more GL images are received (e.g., at processing circuitry 40). As explained above, in one example, the GL images can be images of a semiconductor specimen generated by an examination tool such as a SEM used for imaging a semiconductor specimen.

At block 603 a shape-based analysis is applied on the GL images. One or more GL images undergo a shape-based analysis to identify and delineate object boundaries within each image. The shape-based analysis is applied on a region of interest (ROI) in an image, which can include the entire image or a part of the image. Shape-based analysis can be implemented using any one of various techniques, including, but not limited to, gradient (slope) detection, extremum identification in grayscale values, and kernel convolution, employed to identify and analyze edges in the images.

Shape-based edge detection operates by transforming the value of each pixel through specific functions, to modify the original values of the pixels. This modification is intended to render edges more distinguishable from the image's background. At the heart of this transformation is the objective to increase or diminish the variations in pixel intensity, effectively bringing certain features of the image into focus. These techniques specifically target areas where there is a sharp change in image brightness, which indicates areas of high gradient magnitudes, thereby accentuating the edges.

Considering by way of example a convolution kernel (or filter) for shape-based analysis, it involves the application of a convolution kernel for obtaining effects such as blurring, sharpening, embossing, edge detection, and more, through a process known as convolution (which, in the context of edge detection, mostly, but not exclusively, refers to a correlation operation). In the context of shape-based edge detection, a convolution kernel is designed to highlight edges by enhancing the contrast between adjacent pixels at boundaries. The kernel is slid (or convolved) over the image, and, at each position, a mathematical operation is performed between the part of the image under the kernel and the kernel itself. This operation typically involves multiplying the kernel's values by the corresponding image pixel values and summing the results. For edge detection, kernels are structured to respond strongly to regions of the image with high spatial frequency, where pixel values change abruptly, thus highlighting edges. Common examples of convolution kernels for edge detection include the Sobel, Prewitt, and Roberts Cross operators, each designed with specific patterns to detect horizontal, vertical, and diagonal edges by emphasizing the gradient magnitude.

According to the presently disclosed subject matter, to improve the edge detection obtained by traditional shape-based analysis and obtain edge detection accurately targeting a certain desired feature (e.g., contours, shape and/or pattern) in the image, greyscale dependent transformation is applied in addition to the shape-based analysis. In this manner the shape-based analysis identifies the shape or pattern of interest, and the greyscale dependent transformation further transforms the shape-based analysis output, such that visibility of pixels that fall within a predetermined pixel value range is increased. By this, ambiguities that result from the inability of the shape-based analysis to discriminate between similar edges up to a linearity, are resolved, and the desired feature (e.g., contour shape and/or pattern) can be identified.

In some examples, following application of the shape-based analysis, each pixel in a region of interest (ROI) is transformed a second time by respective regularization coefficient denoted C_{i,j}. A regularization coefficient C_{i,j} can be calculated for each transformed pixel in the ROI (605).

The expression below shows a basic representation of the regularization coefficient calculation.

$$∀ ( i , j ) ∈ ROI , {C}_{i , j} = \frac{1}{\vert {P}_{t -} {P}_{i , j} \vert} \qquad ( 1 )$$

Where:
C_{i,j} is the regularization coefficient calculated for pixel i, j;
Pₜ is a target pixel grey level value (a constant value);
P_{i,j} is the original pixel grey level value of pixel i, j before application of the shape-based analysis;

As apparent from equation (1) the regularization coefficient of pixel i, j is determined based on a reciprocal of a difference between a target pixel grey level value and the actual grey level value.

The target pixel value Pₜ represents the grey level value (e.g., center value) of a sought-after edge (which is part of a feature of interest) in the processed grey level image. Referring to FIG. 2, if the first response (29) with the lower grey level values corresponds to the desired pattern, Pₜ is selected to match a value from the first response, e.g., 15,000 (here the image is a 16-byte image). If, however, the second response (31) with the higher grey level values corresponds to the desired pattern, Pₜ is selected to match a value from the second response, e.g., 45,000.

According to some examples, the process described with reference to FIG. 6 further includes a step of receiving or determining or adjusting target pixel value Pₜ, e.g., to match pixel value of a desired edge in the grey level image that is being processed. The target pixel value Pₜ can be selected for example by a user, e.g., received as a user input. The user can review the image, using, for example, appropriate software tools and a user interface (for example by a GUI accessible via a user terminal operatively connected to system 400) and determine the value of grey level pixels that characterize a sough-after edge. For example, the target pixel value can be determined as an average value of pixels accommodating the sought-after edge. Alternatively, the target pixel value Pₜ can be determined automatically based on predefined parameters.

A second transformed value A_{i,j}^{r} (also referred to herein as “regularized pixel value”) is calculated for pixel i, j based on the respective regularization coefficient and the first transformed grey level value A_{i,j} (607).

$$∀ ( i , j ) ∈ ROI , {A}_{i , j}^{r} = {A}_{i , j} \times {C}_{i , j} = \frac{{A}_{i , j}}{\vert {P}_{t -} {P}_{i , j} \vert} \qquad ( 2 )$$

As apparent from equation 2, calculation of A_{i,j}^{r} can be done in streamline fashion using

$$\frac{{A}_{i , j}}{\vert {P}_{t -} {P}_{i , j} \vert}$$

without first calculating C_{i,j}.

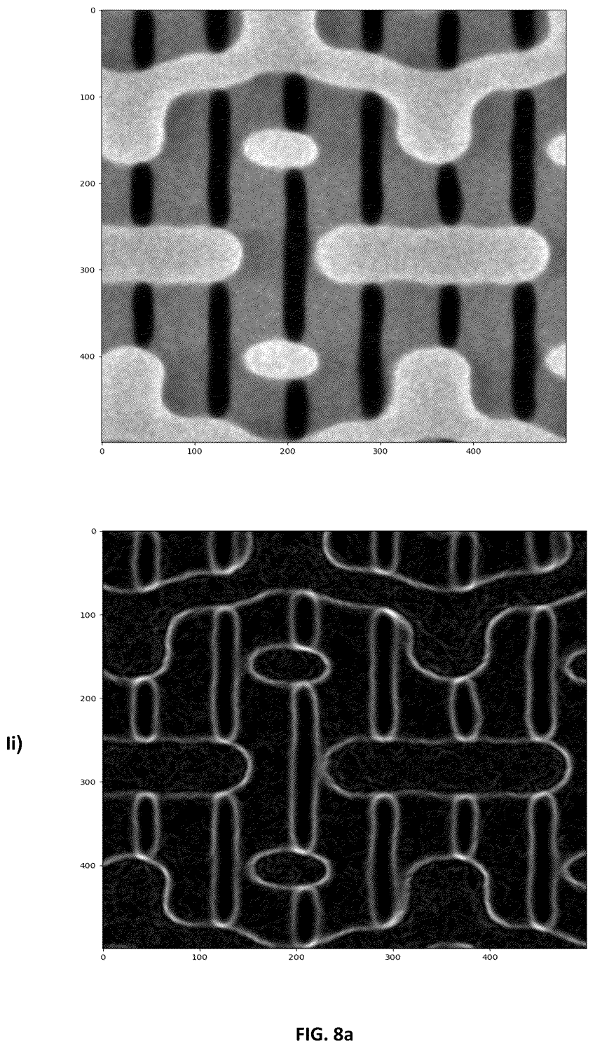

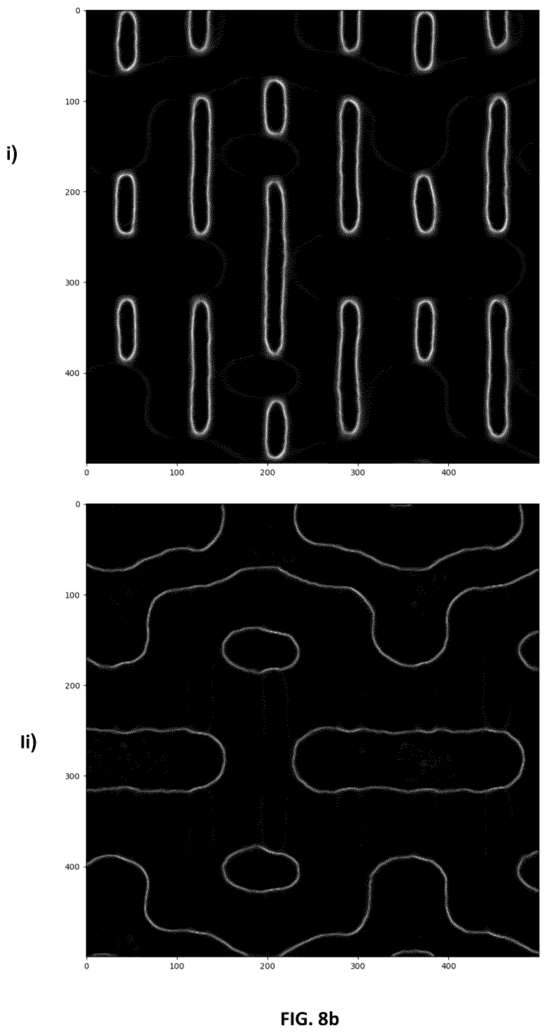

By applying these operations on each pixel in the ROI, the ROI is transformed into a respective output image, composed of the regularized pixel values, in which the visibility of desired edges is emphasized, while the visibility of other undesired edges is diminished according to the Pₜ value, as further demonstrated in FIGS. 8a and 8b below.

The output image generated by the edge detection process described above can be manipulated in any desired manner, including, for example, storing the images in a dedicated computer data-storage unit (e.g., storage unit 422), displayed on a display device (e.g., of user terminal operatively connected to system 400), and/or further analyzed. As mentioned above, in the context of semiconductor examination, identification of edges which are part of certain contours, shapes, and/or patterns of interest in an examination output image (e.g., SEM output image) enables detection of features within the image that characterize the semiconductor specimen and can be used for detecting DOIs (e.g., by anomaly detection module 44).

As equation (1) exhibits the characteristic behavior of

$$f = \frac{1}{x}$$

namely a vertical asymptote at x=0, which is undesirable, functional variations of the regularization coefficient are suggested as alternatives.

A first functional variation is shown by equations 3 and 4, which include modified expressions. The denominator is modified to include a pixel value lower-bound constraint to ensure it does not drop below the value P_{gap}. The modified numerator is the value A_{i,j} multiplied by P_{gap}.

$${C}_{i , j} = \frac{{P}_{gap}}{max ( \vert {P}_{t -} {P}_{i , j ,} \vert , {P}_{gap} )} \qquad ( 3 )$$

$${A}_{i , j}^{r} = {A}_{i , j} \times {C}_{i , j} = \frac{{A}_{i , j} \times {P}_{gap}}{max ( \vert {P}_{t -} {P}_{i , j ,} \vert , {P}_{gap} )} \qquad ( 4 )$$

where equation 3 is a functional variation of the calculation of the regularization coefficient, and equation 4 is a functional variation of the streamline calculation of the regularized pixel value.

A second functional variation is shown by equations 5 and 6, which provide a smooth and continuous function.

$${C}_{i , j} = \frac{{P}_{gap}}{\sqrt{( {( {P}_{t -} {P}_{i , j} )}^{2} + {P}_{gap}^{2} )}} \qquad ( 5 )$$

$${A}_{i , j}^{r} = {A}_{i , j} \times {C}_{i , j} = \frac{{A}_{i , j} \times {P}_{gap}}{\sqrt{( {( {P}_{t -} {P}_{i , j} )}^{2} + {P}_{gap}^{2} )}} \qquad ( 6 )$$

where equation 5 is a second functional variation of the calculation of the regularization coefficient, and equation 6 is a second functional variation of the streamline calculation of the regularized pixel value.

Notably, the value P_{gap} also defines the bounds of the output, namely the range of pixel values which are within the possible solutions of the function. A greater P_{gap} induces a greater range of pixel values i.e., a more lenient discrimination, whereas a smaller P_{gap} induces a smaller range of pixel value, i.e. a stricter discrimination. Low P_{gap} values of the detected edges are within a smaller range, thus imposing a more specific detection of edges, limited to pixels within the respective range of values.

According to some examples, the process described with reference to FIG. 6 further includes a step of receiving or determining or adjusting the P_{gap} value. For example, the user can review the image using, for example, appropriate software tools and a user interface (accessible, for example, via a user terminal) and determine the value of P_{gap} to adjust the strength of the regularization.

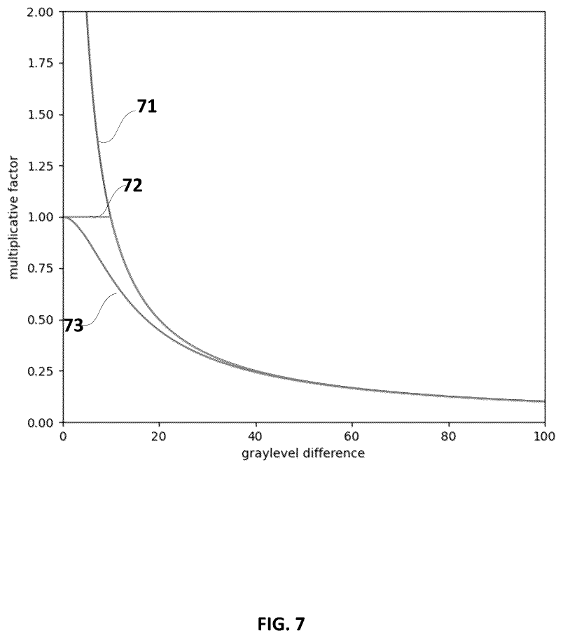

FIG. 7 shows a graph plotting the regularization coefficients (ordinate) relative to the corresponding grey level difference |Pₜ−P_{i,j},| (abscissa). Line 71 corresponds to a basic functional variation represented by equation 1, Line 72 corresponds to the first functional variation represented by equation 3, and Line 73 corresponds to the second functional variation represented by equation 4. As seen in the graph, line 71 is asymptotic where x is near 0, line 72 has a cutoff point at |Pₜ−P_{i,j},|=10, with P_{gap}=10, and line 73 exhibits a smooth and continuous curve towards 1.0.

Referring to FIGS. 8a and 8b, they illustrate a simplified example of the implementation of the regularization coefficient on an GL SEM image. FIG. 8a, (i), is an example of an 8-byte grey level SEM image. The original SEM image comprises patterns extending substantially vertically, characterized by lower grey level values, closer to black, and patterns extending substantially horizontally and characterized by higher grey level values.

FIG. 8a (ii) shows the transformed image resulting from the application of a shape-based analysis (in this case a simple bi-directional gradient) on the SEM image. As apparent from FIG. 8a, the application of the shape-based analysis results in a transformed image, where both the vertical (low grey level values) and horizontal (high grey level values) are equally visible. This result may be undesirable if only the vertical or only the horizontal patterns are of interest.

FIG. 8b, (i) and FIG. 8b item ii, are two examples of two different images generated by the application of regularization on the transformed image shown in FIG. 8a, item ii. FIG. 8b (i) shows an image resulting from the application of the regularization with a target grey level value Pₜ that equals 40, and FIG. 8b (ii) shows an image resulting from the application of the regularization with a target grey level value Pₜ that equals 160. 40 is within the range of the low grey level values characterizing the vertical patterns. As shown in FIG. 8b (i), the vertical patterns are clearly visible, while the horizontal values are invisible. 160, on the other hand, is within the range of the high grey level values of the horizontal patterns. As shown in FIG. 8b (ii), the horizontal patterns are clearly visible, while the vertical values are invisible.

With respect to edge detection, while it is described herein primarily with reference to semiconductor examination output images, this is done for the sake of example only in a non-limiting manner. It should be well understood that the use of the disclosed edge detection technique can be likewise implemented in various other fields of technology, where grey level images are provided as output, including for example, in life sciences, land survey, material science, geology, nanotechnology, etc.

Regarding the equations included in this patent application, they serve to demonstrate the mathematical principles related to the disclosed subject matter, and are offered as examples, without limiting the scope to the specific forms described. Recognizing that identical mathematical principles can be represented by different equations, which may vary in form, but share the same meaning, the inclusion of particular equations is solely for illustrative purposes. Consequently, this application contemplates all equivalent formulations of these principles, ensuring that patent protection is not restricted to the examples provided, but extends to any mathematical expressions that embody the underlying concepts. The term “equivalent thereof” or “any mathematical equivalent thereof” is used in the specification and claims to express the above principle.

While certain examples of the present disclosure refer to a processing circuitry being configured to perform the above recited operations, the functionalities/operations of the aforementioned functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations.

Those versed in the art will readily appreciate that the teachings of the presently disclosed subject matter are not bound by the system illustrated in FIG. 4. Each system component and module in FIG. 4 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 4.

Each component in FIG. 4 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

The system illustrated in FIG. 4 can be implemented in a distributed computing environment, in which one or more of the aforementioned components and functional modules shown in FIG. 4 can be distributed over several local and/or remote devices. By way of example, the examination tool 420 and the system 401 can be located at the same entity (in some cases hosted by the same device) or distributed over different entities, each located at a different location.

In some examples, certain components utilize a cloud implementation, e.g., implemented in a private or public cloud. Communication between the various components of the examination system, in cases where they are not located entirely in one location or in one physical entity, can be realized by any signaling system or communication components, modules, protocols, software languages and drive signals, and can be wired and/or wireless, as appropriate.

It should be further noted that in some embodiments at least some of examination tools 420 and/or storage unit 422 can be external to system 401 and operate in data communication with systems 401 over a suitable communication link. System 401 can be implemented as stand-alone computer(s) to be used in conjunction with the examination tools, and/or with the additional examination modules as described above. Alternatively, the respective functions of system 401 can, at least partly, be integrated with one or more examination tools 420, thereby facilitating and enhancing the functionalities of the examination tools 420 in examination-related processes.

Unless specifically stated otherwise, as apparent from the above discussions, it is appreciated that, throughout the specification, discussions utilizing terms such as “applying”, “calculating”, “generating”, “analyzing”, “using”, “utilizing” or the like, include an action and/or processes of a computer that manipulate and/or transform data into other data, said data represented as physical quantities, e.g. such as electronic quantities, and/or said data representing the physical objects.

The terms “computer”, “computer system”, “computer device”, “computerized device” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a graphics processing unit (GPU), a network processor, or the like. The one or more processors are configured to execute instructions for performing the operations and steps discussed herein.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

In embodiments of the presently disclosed subject matter, fewer, more and/or different stages than those shown in FIGS. 5 and 6 may be executed. In embodiments of the presently disclosed subject matter, one or more stages illustrated in the figures may be executed in a different order, and/or one or more groups of stages may be executed simultaneously.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method of processing grey level (GL) images, wherein the grey level images of a semiconductor specimen; the method comprising using at least one processing circuitry:
applying a shape-based analysis to a region of interest (ROI) in a grey level image, to thereby obtain a transformed ROI comprising pixels transformed by the shape-based analysis; wherein the ROI comprises the entire image or part thereof;
calculating for each transformed pixel i, j in the transformed ROI a respective regularized pixel value A_{i,j}^{r}, based on a ratio between a respective transformed pixel value A_{i,j} or a functional variation thereof and a difference between the original grey level pixel value P_{i,j} before transformation and a target grey level pixel value Pₜ or a functional variation of the difference; wherein the target grey level pixel value Pₜ represents a grey level value of at least one sought-after edge in the grey level image; and
generating an output image, composed of the regularized pixel values, in which visibility of the at least one sought-after edge in the grey level image is emphasized, while visibility of other edges in the grey level image is diminished.

2. The computer-implemented method of claim 1 further comprising:
analyzing the at least one sought-after edge to detect features that characterize the semiconductor specimen; and
using the features for detecting defects of interest in the semiconductor specimen.

3. The computer-implemented method of claim 1, further comprising utilizing an examination tool for scanning the semiconductor specimen and generating the grey level image.

4. The computer-implemented method of claim 3, wherein the examination tool is a Scanning Electron Microscope (SEM).

5. The computer-implemented method of claim 1, wherein the calculation of the respective regularized pixel value A_{i,j}^{r} includes calculating a respective regularization coefficient C_{i,j} expressed as
$$\frac{1}{\vert {P}_{t -} {P}_{i , j} \vert} ,$$
or any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis;
the method comprising applying (e.g., multiplying) the respective regularization coefficient on the transformed pixel value A_{i,j} to thereby obtain the respective regularized pixel value A_{i,j}^{r}.

6. The computer-implemented method of claim 1, wherein the calculation of the respective regularized pixel value A_{i,j}^{r} includes calculating a respective regularization coefficient C_{i,j} expressed as
$$\frac{{P}_{gap}}{max ( \vert {P}_{t -} {P}_{i , j ,} \vert , {P}_{gap} )}$$
or any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis; and
P_{gap} is a pixel value lower-bound constraint;
the method comprising applying the respective regularization coefficient on the transformed pixel value A_{i,j} to thereby obtain the respective regularized pixel value A_{i,j}^{r}.

7. The computer-implemented method of claim 1, wherein the calculation of the respective regularized pixel value A_{i,j}^{r} includes calculating a respective regularization coefficient C_{i,j} expressed as
$$\frac{{P}_{gap}}{\sqrt{( {( {P}_{t -} {P}_{i , j} )}^{2} + {P}_{gap}^{2} )}}$$
or any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis; and
P_{gap} is a pixel value lower-bound constraint;
the method comprising applying the respective regularization coefficient on the transformed pixel value A_{i,j} to thereby obtain the respective regularized pixel value A_{i,j}^{r}.

8. The method of claim 1, further comprising:
defining the target grey level pixel value Pₜ according to pixel values characterizing the at least one sought-after edge.

9. The method of claim 6 further comprising: defining the value of P_{gap} according to characteristics of the grey level image and Pₜ.

10. The method of claim 7 further comprising: defining the value of P_{gap} according to characteristics of the grey level image and Pₜ.

11. A computer system configured and operable to process grey level (GL) images of a semiconductor specimen; the computer system comprising a processing circuitry configured to:
apply a shape-based analysis to a region of interest (ROI) in a grey level image, to thereby obtain a transformed ROI comprising pixels transformed by the shape-based analysis; wherein the ROI comprises the entire image or part thereof;
calculate, for each transformed pixel i, j in the transformed ROI, a respective regularized pixel value A_{i,j}^{r}, based on a ratio between a respective transformed pixel value A_{i,j} or a functional variation thereof and a difference between the original grey level pixel value P_{i,j} before transformation, and a target grey level pixel value Pₜ or a functional variation of the difference; wherein the grey level pixel value Pₜ represents a grey level value of at least one sought-after edge in the grey level image; and
generate an output image, composed of the regularized pixel values, in which visibility of the at least one sought-after edge in the grey level image is emphasized, while visibility of other edges in the grey level image is diminished.

12. The computer system of claim 11, wherein the processing circuitry is configured to:
analyze the at least one contour and/or shape of interest to detect features that characterize the semiconductor specimen; and
use the features for detecting defects of interest in the semiconductor specimen.

13. The computer system of claim 11 comprising or otherwise operatively connected to an examination tool configured for scanning the semiconductor specimen and generating the grey level images.

14. The computer system of claim 13, wherein the examination tool is a Scanning Electron Microscope (SEM).

15. The computer system of claim 11, wherein the processing circuitry is configured for calculating the respective regularized pixel value A_{i,j}^{r} to:
calculate a respective regularization coefficient C_{i,j} expressed as
$$\frac{1}{\vert {P}_{t -} {P}_{i , j} \vert} ,$$
or
any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis;
the method comprising applying the respective regularization coefficient on the transformed pixel value A_{i,j} to thereby obtain the respective regularized pixel value A_{i,j}^{r}.

16. The computer system of claim 11, wherein the processing circuitry is configured for calculating the respective regularized pixel value A_{i,j}^{r} to:
calculate a respective regularization coefficient C_{i,j} expressed as
$$\frac{{P}_{gap}}{max ( \vert {P}_{t -} {P}_{i , j ,} \vert , {P}_{gap} )}$$
or any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis; and
P_{gap} is a pixel value lower-bound constraint;
the method comprising applying the respective regularization coefficient on the transformed pixel value A_{i,j} to thereby obtain the respective regularized pixel value A_{i,j}^{r}.

17. The computer system of claim 11, wherein the processing circuitry is configured for calculating the respective regularized pixel value A_{i,j}^{r} to:
calculate a respective regularization coefficient C_{i,j} expressed as
$$\frac{{P}_{gap}}{\sqrt{( {( {P}_{t -} {P}_{i , j} )}^{2} + {P}_{gap}^{2} )}}$$
or any mathematical equivalent thereof;
wherein:
C_{i,j} is the regularization coefficient calculated for pixel i, j;
Pₜ is a target pixel grey level value;
P_{i,j} is an original pixel grey level value of pixel i, j before application of the shape-based analysis; and
P_{gap} is a pixel value lower-bound constraint;
the method comprising applying the respective regularization coefficient on the transformed pixel value A_{i,j} to thereby obtain the respective regularized pixel value A_{i,j}^{r}.

18. The computer system of claim 11 wherein the processing circuitry is configured to:
enable defining the target grey level pixel value Pₜ according to pixel values characterizing the at least one sought-after edge.

19. The computer system of claim 15, wherein the processing circuitry is configured to enable defining the value of P_{gap} according to characteristics of the grey level image and Pₜ.

20. A non-transitory computer readable medium comprising instructions that, when executed by a computer, cause the computer to perform a method of processing grey level (GL) images of a semiconductor specimen; the method comprising:
applying a shape-based analysis to a region of interest (ROI) in a grey level image, to thereby obtain a transformed ROI comprising pixels transformed by the shape-based analysis; wherein the ROI comprises the entire image or part thereof;
calculating, for each transformed pixel i, j in the transformed ROI, a respective regularized pixel value A_{i,j}^{r}, based on a ratio between a respective transformed pixel value A_{i,j} or a functional variation thereof, and a difference between the original grey level pixel value P_{i,j} before transformation and a target grey level pixel value Pₜ or a functional variation of the difference; wherein the target grey level pixel value Pₜ represents a grey level value of at least one sought-after edge in the grey level image; and
generating an output image, composed of the regularized pixel values, in which visibility of the at least one sought-after edge in the grey level image is emphasized, while visibility of other edges in the grey level image is diminished.
